(19) United States
(12) Patent Application Publication
(10) Pub. No.: US 2015/0137133 A1
(43) Pub. Date: May 21, 2015

(54) FORMING OF A HEAVILY-DOPED SILICON LAYER ON A MORE LIGHTLY-DOPED SILICON SUBSTRATE

(71) Applicants: STMicroelectronics SA, Montrouge (FR); STMICROELECTRONICS (CROLLES 2) SAS, Crolles (FR)

(72) Inventors: Michel Marty, Saint Paul D Varces (FR); Francois Roy, Seyssins (FR)

(73) Assignees: STMICROELECTRONICS SA, Montrouge (FR); STMICROELECTRONICS (CROLLES 2) SAS, Crolles (FR)

(21) Appl. No.: 14/537,992

(22) Filed: Nov. 11, 2014

(30) Foreign Application Priority Data
Nov. 15, 2013 (FR) 1361193

(51) Int. Cl. H01L 21/02; H01L 31/0232; H01L 31/0376

(52) U.S. Cl. CPC H01L 21/02675; H01L 21/02532; H01L 31/03762; H01L 21/02592; H01L 31/02327
USPC 257/75; 438/487

(57) ABSTRACT

A method of forming a heavily-doped silicon layer on a more lightly-doped silicon substrate including the steps of depositing a heavily-doped amorphous silicon layer; depositing a silicon nitride layer; and heating the amorphous silicon layer to a temperature higher than or equal to the melting temperature of silicon.

### PRIORITY CLAIM

This application claims the priority benefit of French Patent application number 1361193, filed on Nov. 15, 2013, the contents of which is hereby incorporated by reference in its entirety to the maximum extent allowable by law.

### TECHNICAL FIELD

The present disclosure relates to a method of forming a heavily-doped silicon layer on a more lightly doped silicon substrate.

### BACKGROUND

FIG. 1 is a cross-section view schematically and partially showing a back-side illuminated image sensor 1. In a P-type substrate 3, insulating regions 5 form partitions dividing the substrate into portions 3a and 3b.

Insulating regions 5 are bordered by a thin layer 7 of the same conductivity type as the substrate but having a higher doping level.

Photodiodes and charge transfer transistors (not shown) are formed in the upper portion of substrate portions 3a. Other transistors (not shown) are formed inside and on top of substrate portions 3b. These other transistors may be shared between several neighboring photodiodes, for example, between four photodiodes associated with four neighboring substrate portions 3a.

The front surface of substrate 3 is covered with a stack 9 of insulating and conductive layers, where the various interconnections of the sensor are formed. In particular, substrate portion 3b is topped with a bias contact area 11 formed in stack 9. Each contact area 11 contacts a P-type region 13 having a higher doping level than the substrate, formed in the upper portion of substrate portion 3b. Of course, bias contact area 11 may be formed at another location. The interconnections tracks and vias other than those forming contact areas 11 have not been shown in FIG. 1.

The substrate is thinned from its rear surface until insulating regions 5 are reached. As an example, the thickness of substrate 3 remaining after thinning is in the range from 1 to 10 μm. Substrate portions 3a, 3b may then be fully insulated from one another by insulating regions 5.

A layer 15 of the same conductivity type as the substrate but having a higher doping level is arranged on the rear surface of substrate 3. A thin insulating layer 17, for example, a silicon oxide layer having a thickness of a few nanometers, is arranged on layer 15. Layer 17 is coated with an antireflection layer 19. Antireflection layer 19 is topped with color filters 21, arranged side-by-side in correspondence with the sensor pixels. A green filter (G) and a blue filter (B) have been shown. Microlenses 23 are formed above each filter.

To form the stack of layers 15, 17, and 19 includes covering the rear surface of substrate 3 with an amorphous silicon layer of the same conductivity type as the substrate but of higher doping level. Immediately after the deposition of the amorphous silicon layer, a crystallization anneal (UV laser anneal) is carried out to form a single-crystal silicon layer 15.

After the recrystallization of layer 15, a thin insulating layer 17, for example, a silicon oxide layer having a thickness of a few nanometers, is formed on layer 15. An antireflection layer 19, for example made of a superposition of several transparent dielectric layers having different indexes, is then deposited on layer 17.

A disadvantage of such a method relates to the anneal step of the amorphous silicon layer. During this step, layer 15 risks being contaminated, particularly by the presence of metal elements (tungsten, molybdenum, for example) from the stack of interconnection layers.

Another disadvantage of such a method relates to the presence of insulating layer 17. Insulating layer 17 being very thin, it does not take part in the antireflection effect and may affect the proper operation of the antireflection structure.

### SUMMARY

Thus, an embodiment provides a method of forming a heavily-doped silicon layer on a more lightly-doped silicon substrate, the method comprising the steps of: a) depositing a heavily-doped amorphous silicon layer; b) depositing a silicon nitride layer; and c) heating the amorphous silicon layer to a temperature greater than or equal to the silicon melting temperature.

According to an embodiment, the amorphous silicon layer is heated by laser illumination.

According to an embodiment, the amorphous silicon and silicon nitride layers are successively deposited in a same enclosure, with no intermediate exposure to the atmosphere.

According to an embodiment, the amorphous silicon layer has the same conductivity type as the silicon substrate.

According to an embodiment, the doping level of the amorphous silicon is in the range from 10¹⁸ to 10²⁰ at./cm³.

According to an embodiment, the thickness of the amorphous silicon layer is in the range from 10 to 150 nm.

According to an embodiment, the thickness of the silicon nitride layer is in the range from 35 to 60 μm.

An embodiment provides a back-side illuminated image sensor wherein the amorphous silicon layer and the silicon nitride layer are formed by the above method.

According to an embodiment, the silicon nitride layer is an antireflection layer.

### BRIEF DESCRIPTION OF THE DRAWINGS

The foregoing and other features and advantages will be discussed in detail in the following non-limiting description of specific embodiments in connection with the accompanying drawings.

FIG. 1, previously described, is a cross-section view schematically and partially showing a back-side illuminated image sensor;

FIGS. 2A and 2B are partial simplified cross-section views illustrating steps of an embodiment of the method described herein; and

FIG. 3 is a partial simplified cross-section view illustrating an embodiment of a back-side illuminated image sensor obtained by the method described herein.

### DETAILED DESCRIPTION OF THE DRAWINGS

For clarity, the same elements have been designated with the same reference numerals in the various drawings and, further, as usual in the representation of integrated circuits, the various drawings are not to scale.

FIGS. 2A and 2B are partial simplified cross-section views illustrating two steps of an embodiment of a method of forming a heavily-doped silicon layer on a more lightly-doped silicon substrate.

FIG. 2A shows a silicon substrate 30 coated with a heavily-doped amorphous silicon layer 32 and with a silicon nitride layer 34.

Heavily-doped silicon layer 32 is an amorphous silicon layer which may be deposited at low temperature, for example, at a temperature lower than 400° C. Layer 32 has the same conductivity type as substrate 30 but a higher doping level. Layer 32 is deposited over the entire surface of substrate 30.

Silicon nitride layer 34 is deposited on amorphous silicon layer 32 in the same equipment as that which has been used to deposit layer 32, with no intermediate anneal and in a non-oxidizing environment, to avoid the forming of a thin silicon oxide layer. The deposition may be performed in other equipment, but with no intermediate exposure to the atmosphere.

As illustrated in FIG. 2B, once layers 32 and 34 have been deposited, an anneal is carried out to crystallize amorphous silicon layer 32 and to turn it into a silicon layer 35 in crystal continuity with single-crystal substrate 30, of the same conductivity type as silicon substrate 30 but having a higher doping level.

The anneal is for example carried out by laser illumination, symbolized by arrows 36. This enables to strongly raise the temperature of amorphous silicon layer 32 and of the neighboring region of substrate 30 while maintaining a low temperature in the rest of substrate 30. It is thus avoided to degrade possible components already formed on the other surface of substrate 30. The intensity of the laser beam is selected so that the thin heated area is heated to a temperature greater than the melting temperature of amorphous silicon (1,100° C.) and of crystal silicon (1,414° C.) and lower than the melting temperature of silicon nitride (1,900° C.). The advantage of such method is that silicon layer 35 does not risk being polluted by possible contaminants since the anneal is then performed while silicon nitride layer 34 covers and protects amorphous silicon layer 32, as it is being transformed by the anneal into silicon layer 35.

Another advantage of this method is the decrease of the laser power necessary to obtain the melting of silicon, layer 34 behaving as an antireflection layer at the time of the laser illumination (less parasitic reflection of the laser beam).

FIG. 3 is a partial simplified cross-section view illustrating an embodiment of a back-side illuminated image sensor manufactured with the method of forming a heavily-doped silicon layer on a more lightly-doped silicon substrate.

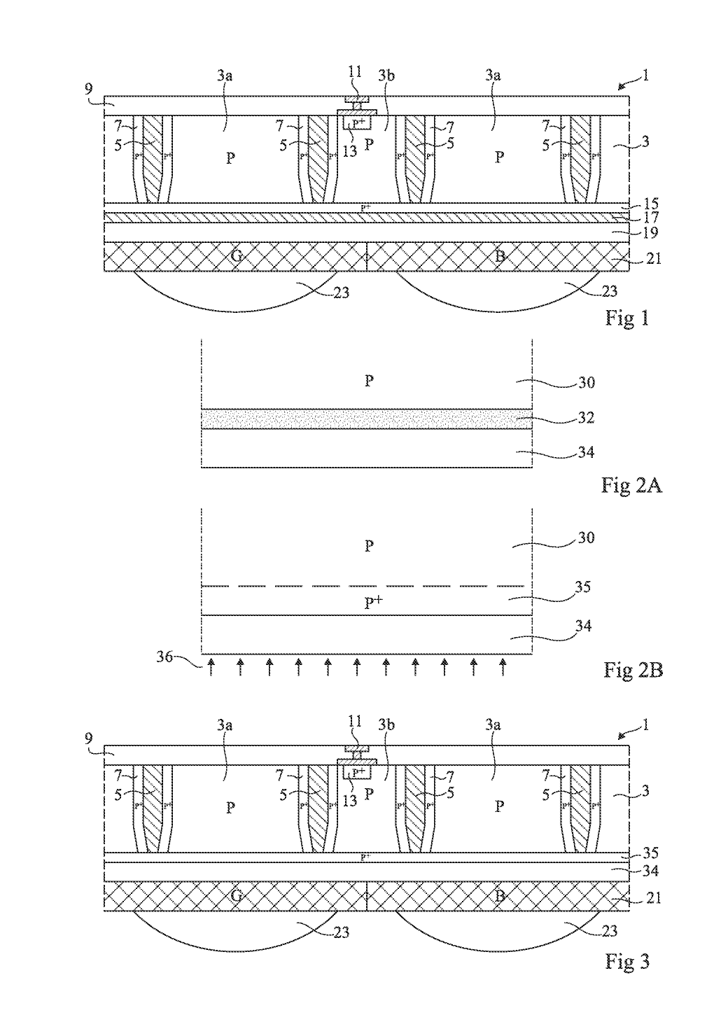

FIG. 3 shows an image sensor structure similar to that described in relation with FIG. 1. However, layers 15, 17, and 19 are replaced with layer 35 and 34 formed by the method described in relation with FIGS. 2A and 2B.

The structure of FIG. 3, like that of FIG. 1, comprises a substrate 3, a stack 9 of insulating and conductive layers on its front surface, and insulating regions 5 forming vertical partitions which cross substrate 3. The partitions are laterally bordered by a thin layer 7, of the same conductivity type as substrate 3 but of higher doping level.

Thus, the amorphous silicon layer deposited on the rear surface is mainly in contact with silicon regions of substrate 3, but also, locally, with rear portions of insulating partitions 5, currently made of silicon oxide.

In this application, silicon nitride layer 34 is used as an antireflection structure and is topped with filters 21, arranged side-by-side in correspondence with the sensor pixels. A green filter (G) and a blue filter (B) have been shown. Microlenses 23 are formed above each filter.

It should be noted that, after the anneal provided herein after the deposition of silicon nitride layer 34, layer 35 may become, as described in relation with FIGS. 2A and 2B, a uniform heavily-doped single-crystal silicon layer 35. However, according to the thickness of the deposited amorphous silicon layer and to the anneal conditions, the crystallization may be interrupted at the locations where the initial amorphous silicon layer is in contact with the rear portions of insulating partitions 5. It will be within the abilities of those skilled in the art to connect and use the image sensor to take into account the fact of being in one or the other of the above-mentioned configurations (complete recrystallization of the amorphous silicon layer or no recrystallization at the rear portions of insulating regions 5) or of being in an intermediate configuration (partial recrystallization of the amorphous silicon layer in front of the rear portions of insulating regions 5).

As an example of numerical values:
the amorphous silicon thickness is in the range from 10 to 150 nm, for example, 50 nm;
the silicon nitride thickness is in the range from 35 to 60 μm, for example, 45 μm;
the thickness of the thinned silicon substrate is in the range from 1 to 10 μm, for example, 5 μm;
the amorphous silicon deposition temperature is lower than 400° C., for example, 200° C.;
the silicon nitride deposition temperature is in the range from 200 to 400° C.

Although amorphous silicon layer 35 has been described as being a heavily-doped layer of the same conductivity type as the substrate, it may be heavily doped with a conductivity type opposite to that of the substrate. In this case, it may play the role of the N electrode of the junction.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

1. A method of forming on a silicon substrate a more-doped silicon layer and a silicon nitride layer, the method comprising the following successive steps:
a) depositing on the substrate a heavily-doped amorphous silicon layer;
b) depositing on the amorphous silicon layer a silicon nitride layer; and
c) heating the amorphous silicon layer to a temperature greater than or equal to the melting temperature of silicon.

2. The method of claim 1, wherein heating of the amorphous silicon layer comprises performing a laser illumination.

3. The method of claim 1, wherein the amorphous silicon and silicon nitride layers are successively deposited in a same enclosure, with no intermediate exposure to the atmosphere.

4. The method of claim 1, wherein the amorphous silicon layer is of the same conductivity type as the silicon substrate.

5. The method of claim 1, wherein a doping level of the amorphous silicon is in the range from 10¹⁸ to 10²⁰ at./cm³.

6. The method of claim 1, wherein a thickness of the amorphous silicon layer is in the range from 10 to 150 nm.

7. The method of claim 1, wherein a thickness of the silicon nitride layer is in the range from 35 to 60 μm.

8. A back-side illuminated image sensor, comprising:
a crystallized amorphous silicon layer;
a silicon nitride layer;
wherein the crystallized amorphous silicon layer and silicon nitride layer are formed an amorphous silicon layer and a silicon nitride layer using the method of claim 1.

9. The back-side illuminated image sensor of claim 8, wherein the silicon nitride layer is an antireflection layer.
